(19) United States
(12) Patent Application Publication
(10) Pub. No.: US 2026/0198368 A1
(43) Pub. Date: Jul. 9, 2026

(54) ELECTRONIC PACKAGE STRUCTURE AND METHOD FOR MANUFACTURING THE SAME

(71) Applicant: Advanced Semiconductor Engineering, Inc., Kaohsiung (TW)

(72) Inventors: Meng-Wei HSIEH, Kaohsiung (TW); Fan-Yu MIN, Kaohsiung (TW); Wei-Hang TAI, Kaohsiung (TW); Shi-Zen CHENG, Kaohsiung (TW); Yi Chun CHOU, Kaohsiung (TW); Wen-Hsuan WANG, Kaohsiung (TW); Chih-En WANG, Kaohsiung (TW); Chao Wei LIU, Kaohsiung (TW)

(73) Assignee: Advanced Semiconductor Engineering, Inc., Kaohsiung (TW)

(21) Appl. No.: 19/239,883

(22) Filed: Jun. 16, 2025

Related U.S. Application Data
(60) Provisional application No. 63/743,590, filed on Jan. 9, 2025.

(51) Int. Cl. H01L 23/31; H01L 23/00

(52) U.S. Cl. CPC H10W 74/121; H10W 42/121; H10W 74/124; H10W 90/734

(57) ABSTRACT

An electronic package structure and a method for manufacturing the same are provided. The electronic package structure includes a metal-containing layer, an electronic component, an encapsulant and a reinforcement structure. The electronic component is disposed over the metal-containing layer. The encapsulant encapsulates the electronic component, and defines a designated cavity. The reinforcement structure contacts the metal-containing layer, and overlaps a vertical projection of the designated cavity. A rigidity of the reinforcement structure is greater than a rigidity of the metal-containing layer.

### CROSS-REFERENCE TO RELATED APPLICATION

This application claims the benefit of and priority to U.S. Provisional Patent Application 63/743,590, filed Jan. 9, 2025, which is incorporated herein by reference in its entirety.

### BACKGROUND

### 1. Field of the Disclosure

The present disclosure relates to an electronic package structure and a method for manufacturing the same, and to an electronic package structure including a metal-containing layer and a method for manufacturing the same.

### 2. Description of the Related Art

The FOPOP (Fan Out Package On Package) structure has poor heat dissipation. Thus, in an existing semiconductor package structure, at least two electronic components are mounted on a substrate side-by-side, and an encapsulant is formed to encapsulate the at least two electronic components concurrently. The yield of the semiconductor package structure may decrease.

### SUMMARY

In some embodiments, an electronic package structure includes a metal-containing layer, an electronic component, an encapsulant and a reinforcement structure. The electronic component is disposed over the metal-containing layer. The encapsulant encapsulates the electronic component, and defines a designated cavity. The reinforcement structure contacts the metal-containing layer, and overlaps a vertical projection of the designated cavity. A rigidity of the reinforcement structure is greater than a rigidity of the metal-containing layer.

In some embodiments, an electronic package structure includes a metal-containing layer, a first electronic component, a first encapsulant and a second encapsulant. The first electronic component is electrically connected to the metal-containing layer. The first encapsulant is disposed on a top surface of the metal-containing layer, and encapsulates the first electronic component. The first encapsulant defines a designated cavity extending through the first encapsulant. The second encapsulant is disposed on a bottom surface of the metal-containing layer.

In some embodiments, a method for manufacturing an electronic package structure includes: attaching a first electronic component on a top surface of a metal-containing layer; attaching a protection material on the top surface of the metal-containing layer; forming a first encapsulant on the metal-containing layer to encapsulate the first electronic component and the protection material; and removing the protection material and a portion of the first encapsulant disposed on the protection material, so that the first encapsulant defines a designated cavity extending through the first encapsulant.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic package structure according to some embodiments of the present disclosure.

FIG. 2 illustrates an enlarged view of an area “A” of FIG. 1.

FIG. 3 illustrates a top view of the electronic package structure of FIG. 1, wherein the second electronic component and the filling material are omitted.

FIG. 4 illustrates a top view of the electronic package structure of FIG. 1, wherein the second electronic component, the filling material and the second conductive pads are omitted.

FIG. 5 illustrates a cross-sectional view of an electronic package structure according to some embodiments of the present disclosure.

FIG. 6 illustrates an enlarged view of an area “B” of FIG. 5.

FIG. 7 illustrates one or more stages of an example of a method for manufacturing an electronic package structure according to some embodiments of the present disclosure.

FIG. 8 illustrates one or more stages of an example of a method for manufacturing an electronic package structure according to some embodiments of the present disclosure.

FIG. 9 illustrates one or more stages of an example of a method for manufacturing an electronic package structure according to some embodiments of the present disclosure.

FIG. 10 illustrates one or more stages of an example of a method for manufacturing an electronic package structure according to some embodiments of the present disclosure.

FIG. 11 illustrates one or more stages of an example of a method for manufacturing an electronic package structure according to some embodiments of the present disclosure.

FIG. 12 illustrates one or more stages of an example of a method for manufacturing an electronic package structure according to some embodiments of the present disclosure.

FIG. 13 illustrates one or more stages of an example of a method for manufacturing an electronic package structure according to some embodiments of the present disclosure.

FIG. 14 illustrates one or more stages of an example of a method for manufacturing an electronic package structure according to some embodiments of the present disclosure.

FIG. 15 illustrates one or more stages of an example of a method for manufacturing an electronic package structure according to some embodiments of the present disclosure.

FIG. 16 illustrates one or more stages of an example of a method for manufacturing an electronic package structure according to some embodiments of the present disclosure.

FIG. 17 illustrates one or more stages of an example of a method for manufacturing an electronic package structure according to some embodiments of the present disclosure.

FIG. 18 illustrates one or more stages of an example of a method for manufacturing an electronic package structure according to some embodiments of the present disclosure.

FIG. 19 illustrates one or more stages of an example of a method for manufacturing an electronic package structure according to some embodiments of the present disclosure.

FIG. 20 illustrates one or more stages of an example of a method for manufacturing an electronic package structure according to some embodiments of the present disclosure.

FIG. 21 illustrates one or more stages of an example of a method for manufacturing an electronic package structure according to some embodiments of the present disclosure.

FIG. 22 illustrates one or more stages of an example of a method for manufacturing an electronic package structure according to some embodiments of the present disclosure.

FIG. 23 illustrates one or more stages of an example of a method for manufacturing an electronic package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

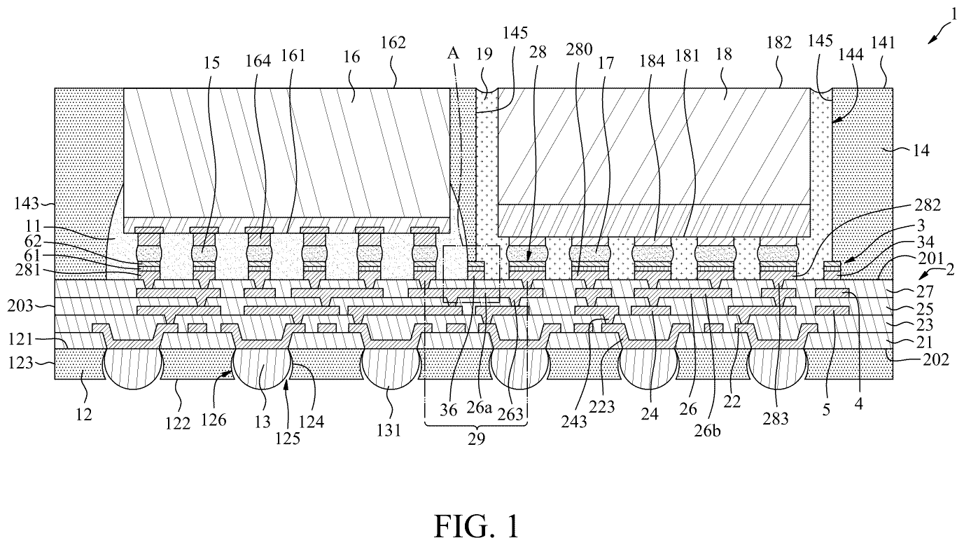

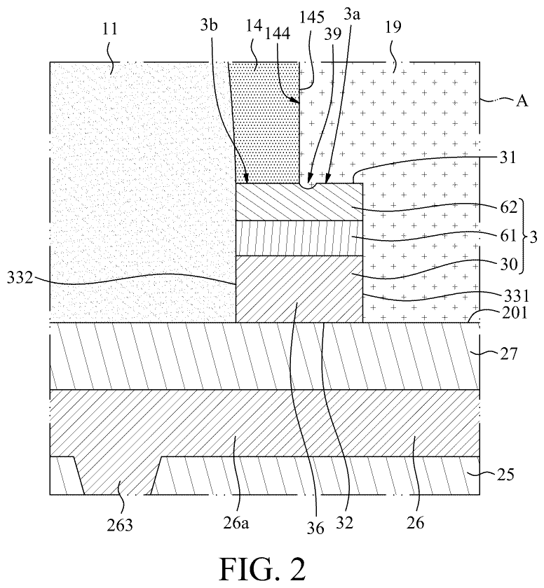

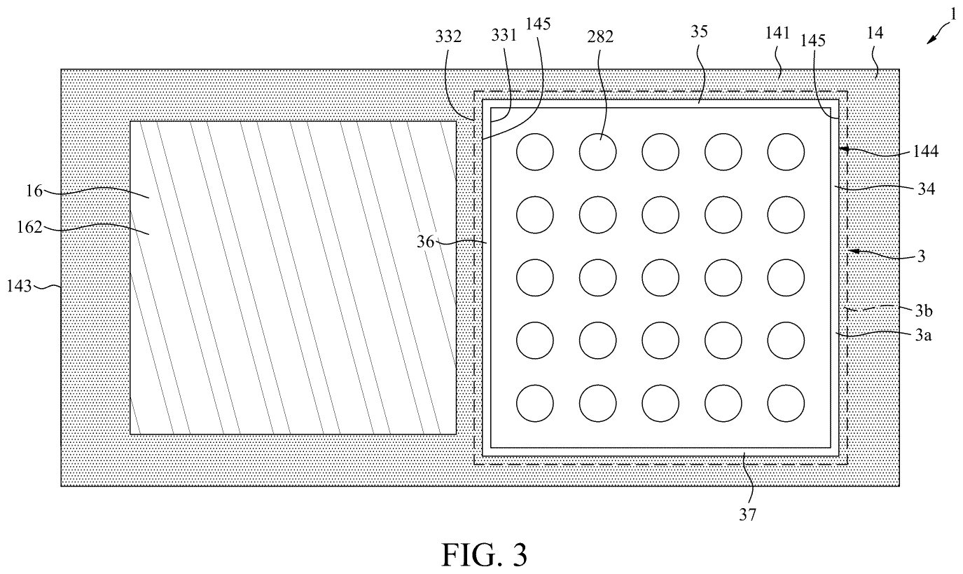

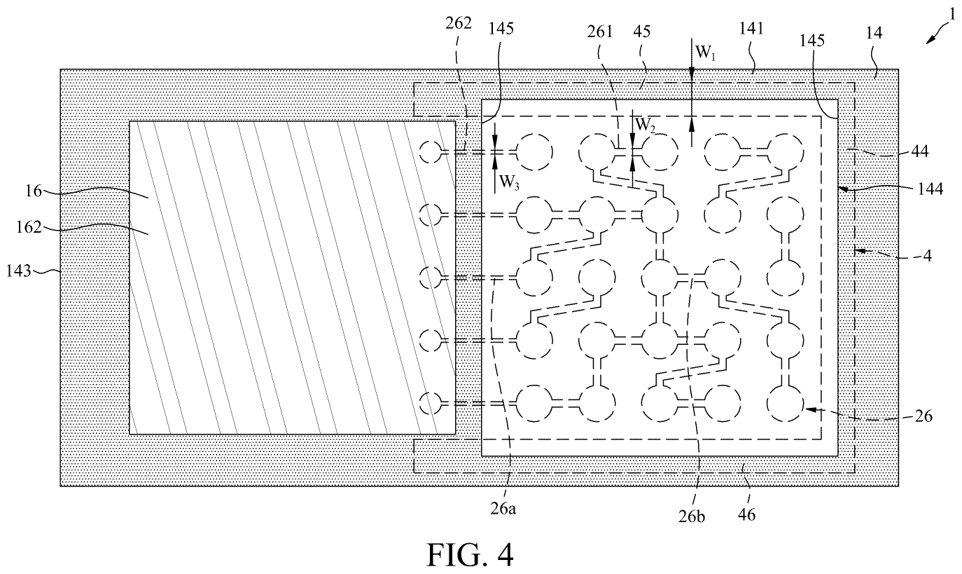

FIG. 1 illustrates a cross-sectional view of an electronic package structure 1 according to some embodiments of the present disclosure. FIG. 2 illustrates an enlarged view of an area “A” of FIG. 1. FIG. 3 illustrates a top view of the electronic package structure 1 of FIG. 1, wherein the second electronic component 18 and the filling material 19 are omitted. FIG. 4 illustrates a top view of the electronic package structure 1 of FIG. 1, wherein the second electronic component 18, the filling material 19 and the second conductive pads 282 are omitted.

The electronic package structure 1 may include a metal-containing layer 2, a reinforcement structure, a first electronic component 16, an underfill 11, a first encapsulant 14, a second electronic component 18, a second encapsulant 12, a plurality of external connectors 13 and a filling material 19. In some embodiments, the electronic package structure 1 may be an assembly structure, a semiconductor package structure, an electronic structure, an electronic device or a semiconductor device.

The metal-containing layer 2 may be, for example, a circuit pattern structure, a wiring structure, a substrate, an interposer, a package structure, a redistribution structure, or a stacked structure. The metal-containing layer 2 may be a routing structure or a redistribution layer (RDL) structure. The metal-containing layer 2 may have a first surface 201 (e.g., a top surface), a second surface 202 (e.g., a bottom surface) opposite to the first surface 201, and a lateral surface 203 extending between the first surface 201 and the second surface 202. The metal-containing layer 2 may include at least one dielectric layer (including, for example, a first dielectric layer 21, a second dielectric layer 23, a third dielectric layer 25 and a fourth dielectric layer 27), at least one circuit layer (including, for example, a first circuit layer 22, a second circuit layer 24, a third circuit layer 26 and a fourth circuit layer 28) in contact with or interposed between the dielectric layers 21, 23, 25, 27, and a plurality of conductive vias (including, for example, a plurality of first conductive vias 223, a plurality of second conductive vias 243, a plurality of third conductive vias 263 and a plurality of fourth conductive vias 283) embedded in the dielectric layers 21, 23, 25, 27.

In some embodiments, each of the dielectric layers (including, for example, the first dielectric layer 21, the second dielectric layer 23, the third dielectric layer 25 and the fourth dielectric layer 27) may include, or be formed from, a photoresist layer, a passivation layer, a cured photo sensitive material, a cured photoimageable dielectric (PID) material such as epoxy, polypropylene (PP), or polyimide (PI) including photoinitiators, or a combination of two or more thereof.

Each of the circuit layers 22, 24, 26, 28 may be a redistribution layer (RDL), and may include a plurality of traces and a plurality of pads. The circuit layers 22, 24, 26, 28 are electrically connected to one another through the conductive vias 243, 263, 283. The first dielectric layer 21 is an outermost dielectric layer, and may define a plurality of openings extending through the first dielectric layer 21. The bottom surface of the first dielectric layer 21 may be the second surface 202 (e.g., the bottom surface) of the metal-containing layer 2. The first circuit layer 22 may be formed or disposed on the first dielectric layer 21. The first conductive vias 223 are disposed in the openings of the first dielectric layer 21 and extend through the first dielectric layer 21 to be exposed by a bottom surface of the first dielectric layer 21. In some embodiments, the first circuit layer 22 and the first conductive vias 223 are formed integrally and concurrently. That is, the first conductive vias 223 are portions of the first circuit layer 22. In some embodiments, the first circuit layer 22 and the first conductive vias 223 may include a seed layer and a plated material disposed on the seed layer. In addition, the first conductive vias 223 may taper downward or taper toward the second surface 202 (e.g., the bottom surface) of the metal-containing layer 2.

The second dielectric layer 23 may be formed or disposed on the first dielectric layer 21 to cover the first circuit layer 22. Further, the second dielectric layer 23 may define a plurality of openings extending through the second dielectric layer 23. The second circuit layer 24 may be formed or disposed on the second dielectric layer 23. The second conductive vias 243 are disposed in the openings of the second dielectric layer 23 and extend through the second dielectric layer 23 to contact the first circuit layer 22. Thus, the second circuit layer 24 is electrically connected to the first circuit layer 22 through the second conductive vias 243. In some embodiments, the second circuit layer 24 and the second conductive vias 243 may be formed integrally and concurrently. In some embodiments, the second circuit layer 24 and the second conductive vias 243 may include a seed layer and a plated material disposed on the seed layer. In addition, the second conductive vias 243 may taper downward or taper toward the first circuit layer 22.

The third dielectric layer 25 may be formed or disposed on the second dielectric layer 23 to cover the second circuit layer 24. Further, the third dielectric layer 25 may define a plurality of openings extending through the third dielectric layer 25. The third circuit layer 26 may be formed or disposed on the third dielectric layer 25. The third conductive vias 263 are disposed in the openings of the third dielectric layer 25 and extend through the third dielectric layer 25 to contact the second circuit layer 24. Thus, the third circuit layer 26 may be electrically connected to the second circuit layer 24 through the third conductive vias 263. In some embodiments, the third circuit layer 26 and the third conductive vias 263 may be formed integrally and concurrently. In some embodiments, the third circuit layer 26 and the third conductive vias 263 may include a seed layer and a plated material disposed on the seed layer. In addition, the third conductive vias 263 may taper downward or taper toward the second circuit layer 24.

The third circuit layer 26 may include an interconnection portion 26a and a periphery portion 26b. The interconnection portion 26a is located in a high line density region 29 (or a fine line region) between the first electronic component 16 and the second electronic component 18. The periphery portion 26b is located outside the high line density region 29. For example, the second electronic component 18 may be electrically connected to the first electronic component 16 through the interconnection portion 26a of the third circuit layer 26. The second electronic component 18 and the first electronic component 16 may be electrically connected to the external connectors 13 through the periphery portion 26b of the third circuit layer 26. A line width/line space (L/S) of the traces of the interconnection portion 16a may be less than an L/S of the traces of the periphery portion 26b. For example, an L/S of the traces of the interconnection portion 26a may be less than or equal to about 5 μm/about 5 μm, or less than or equal to about 2 μm/about 2 μm, or less than or equal to about 0.8 μm/about 0.8 μm. An L/S of the traces of the periphery portion 26b may be less than or equal to about 10 μm/about 10 μm, or less than or equal to about 7 μm/about 7 μm, or less than or equal to about 5 μm/about 5 μm.

The fourth dielectric layer 27 may be formed or disposed on the third dielectric layer 25 to cover the third circuit layer 26. A top surface of the fourth dielectric layer 27 may be the first surface 201 (e.g., the top surface) of the metal-containing layer 2. Further, the fourth dielectric layer 27 may define a plurality of openings extending through the fourth dielectric layer 27. The fourth circuit layer 28 may be formed or disposed on the fourth dielectric layer 27. The fourth conductive vias 283 are disposed in the openings of the fourth dielectric layer 27 and extend through the fourth dielectric layer 27 to contact the third circuit layer 26. Thus, the fourth circuit layer 28 may be electrically connected to the third circuit layer 26 through the fourth conductive vias 283.

In some embodiments, the fourth circuit layer 28 may include a main structure 280, a barrier layer 61 and a wetting layer 62. The main structure 280 (e.g., a copper (Cu) layer) may be formed or disposed on the fourth dielectric layer 27. The barrier layer 61 (e.g., a nickel (Ni) layer) may be formed on the main structure 280. The wetting layer 62 (e.g., a gold (Au) layer) may be formed on the barrier layer 61. The barrier layer 61 and the wetting layer 62 are collectively define an under-bump-metallurgy (UBM) structure. The main structure 280, the barrier layer 61 and the wetting layer 62 may collectively form the fourth circuit layer 28. However, in some embodiments, the barrier layer 61 and the wetting layer 62 may be omitted, and the fourth circuit layer 28 may only include the main structure 280.

In some embodiments, the main structure 280 of the fourth circuit layer 28 and the fourth conductive vias 283 may be formed integrally and concurrently. In some embodiments, the main structure 280 of the fourth circuit layer 28 and the fourth conductive vias 283 may include a seed layer and a plated material disposed on the seed layer. In addition, the fourth conductive vias 283 may taper downward or taper toward the third circuit layer 26.

In some embodiments, the fourth circuit layer 28 may include a plurality of first conductive pads 281 (or protrusion bumps) and a plurality of second conductive pads 282 (or protrusion bumps) extending beyond or protruding from the first surface 201 (e.g., the top surface) of the metal-containing layer 2. Both of the first conductive pad 281 and the second conductive pad 282 may include the main structure 280, the barrier layer 61 and the wetting layer 62. The first conductive pads 281 and the second conductive pads 282 are real conductive pads disposed on the first surface 201 (e.g., the top surface) of the metal-containing layer 2, and are electrically connected to the circuit layers 26, 24, 22 of the metal-containing layer 2.

The reinforcement structure may contact the metal-containing layer 2, and may be configured to reduce a warpage of the metal-containing layer 2. A rigidity of the reinforcement structure may be greater than a rigidity of the metal-containing layer 2. In some embodiments, the reinforcement structure may include a dummy pad 3 (or a dummy structure) disposed on the first surface 201 (e.g., the top surface) of the metal-containing layer 2. The dummy pad 3 may be electrically insulated from the circuit layers 28, 26, 24, 22 of the metal-containing layer 2. That is, the dummy pad 3 may have no electrical function, and may not in an electrical path. The dummy pad 3 may be a block structure, a blocking structure or a dam structure.

As shown in FIG. 1, the dummy pad 3 may be disposed at least two sides of all of the second conductive pads 282. As shown in FIG. 3, the dummy pad 3 (e.g., the reinforcement structure) may be in a ring shape or an annular shape from a top view. The dummy pad 3 (e.g., the reinforcement structure) may include a first strip portion 34, a second strip portion 35, a third strip portion 36 and a fourth strip portion 37 connecting one and another. The first strip portion 34, the second strip portion 35, the third strip portion 36 and the fourth strip portion 37 of the dummy pad 3 (e.g., the reinforcement structure) may surround all of the second conductive pads 282.

As shown in FIG. 1, in some embodiments, the dummy pad 3 (e.g., the reinforcement structure) and the fourth circuit layer 28 (including the first conductive pads 281 and the second conductive pads 282) may be at the same layer and may be formed concurrently. Thus, the dummy pad 3 (e.g., the reinforcement structure) may include a main structure 30, the barrier layer 61 and the wetting layer 62. The main structure 30 (e.g., a copper (Cu) layer) may be formed or disposed on the fourth dielectric layer 27. The barrier layer 61 (e.g., a nickel (Ni) layer) may be formed on the main structure 30. The wetting layer 62 (e.g., a gold (Au) layer) may be formed on the barrier layer 61. However, in some embodiments, the barrier layer 61 and the wetting layer 62 may be omitted, and the dummy pad 3 (e.g., the reinforcement structure) may only include the main structure 30.

As shown in FIG. 2, the dummy pad 3 (e.g., the reinforcement structure) may have a top surface 31, a bottom surface 32 opposite to the top surface 31, an inner lateral surface 331 extending between the top surface 31 and the bottom surface 32, and an outer lateral surface 332 extending between the top surface 31 and the bottom surface 32. The bottom surface 32 of the dummy pad 3 (e.g., the reinforcement structure) may be disposed on the first surface 201 (e.g., the top surface) of the metal-containing layer 2. The dummy pad 3 (e.g., the reinforcement structure) may define a recess portion 39 recessed from the top surface 31 of the dummy pad 3. The recess portion 39 may be formed by laser ablation during a manufacturing process.

As shown FIG. 1, the reinforcement structure may include a first reinforcement structure 4. The first reinforcement structure 4 may be disposed within the metal-containing layer 2. For example, the first reinforcement structure 4 may be disposed on the third dielectric layer 25. As shown FIG. 4, the first reinforcement structure 4 may be disposed around the third circuit layer 26 of the metal-containing layer 2. The first reinforcement structure 4 may be in a substantially U shape from a top view. The first reinforcement structure 4 may include a first strip portion 44, a second strip portion 55 and a third strip portion 46 connecting one and another.

The first strip portion 44, the second strip portion 45 and the third strip portion 46 of the first reinforcement structure 4 may be disposed around the third circuit layer 26. As shown in FIG. 4, a width W₁ of the strip portions 44, 45, 46 of the first reinforcement structure 4 may be greater than a width W₂ of the trace 261 of the periphery portion 26b of the third circuit layer 26 of the metal-containing layer 2. The width W₂ of the trace 261 of the periphery portion 26b of the third circuit layer 26 of the metal-containing layer 2 may be greater than a width W3 of the trace 262 of the interconnection portion 26a of the third circuit layer 26 of the metal-containing layer 2. As shown in FIG. 1, in some embodiments, the first reinforcement structure 4 and the third circuit layer 26 may be at the same layer and may be formed concurrently.

As shown FIG. 1, the reinforcement structure may include a second reinforcement structure 5 disposed within the metal-containing layer 2. For example, the third reinforcement structure 5 may be disposed on the second dielectric layer 23. The second reinforcement structure 5 may be disposed around the second circuit layer 24 of the metal-containing layer 2. The second reinforcement structure 5 may be in a substantially U shape from a top view. The structure of the second reinforcement structure 5 may be the same as the structure of first reinforcement structure 4. The second reinforcement structure 5 and the second circuit layer 24 may be at the same layer and may be formed concurrently.

The first electronic component 16 may be an electronic element or an electronic device, such as a semiconductor chip (e.g., a logic die or a memory die) or a passive element (e.g., a resistor, an inductor or a capacitor). The first electronic component 16 may have a first surface 161 (e.g., a bottom surface) and a second surface 162 (e.g., a top surface) opposite to the first surface 161. The first surface 161 (e.g., the bottom surface) may be an active surface. The second surface 162 (e.g., the top surface) may be a backside surface. The first electronic component 16 may include a plurality of conductive bumps 164 extending beyond the first surface 161 (e.g., the bottom surface). The conductive bumps 164 of the first electronic component 16 may be electrically connected to the first conductive pads 281 of the metal-containing layer 2 through a plurality of solder materials 15. Thus, the first electronic component 16 may be disposed over and may be electrically connected to the metal-containing layer 2.

In addition, the underfill 11 may be formed or disposed between the first electronic component 16 and the metal-containing layer 2 so as to cover and protect the connection formed by the conductive bumps 164, the first conductive pads 281 and the solder materials 15. The underfill 11 may contact the dummy pad 3 (e.g., the reinforcement structure). The underfill 11 may be blocked by the dummy pad 3 (e.g., the reinforcement structure) during the manufacturing process. Thus, the dummy pad 3 (e.g., the reinforcement structure) may prevent the underfill 11 from contacting the second conductive pads 282.

The first encapsulant 14 may be disposed on the first surface 201 (e.g., the top surface) of the metal-containing layer 2. The first encapsulant 14 may be an epoxy molding compound with or without filler. The first encapsulant 14 may encapsulate the first electronic component 16, the underfill 11 and the dummy pad 3 (or the dummy structure). The first encapsulant 14 may define a cavity 144 (e.g., a designated cavity, an accommodating space or an accommodating cavity) extending through the first encapsulant 14. The first encapsulant 14 may have a top surface 141, an outer lateral surface 143 and an inner lateral surface 145. The cavity 144 may be defined by the inner lateral surface 145. Thus, the cavity 144 may have a sidewall 145. The outer lateral surface 143 of the first encapsulant 14 may be substantially aligned with or substantially coplanar with the lateral surface 203 of the metal-containing layer 2. The top surface 141 of the first encapsulant 14 may be substantially aligned with or substantially coplanar with the second surface 162 (e.g., the top surface) of the first electronic component 16.

The dummy pad 3 (or the dummy structure) may overlap a vertical projection of the cavity 144 (or an accommodating cavity). A portion of the first surface 201 (e.g., the top surface) of the metal-containing layer 2 (i.e., a portion of the top surface of the fourth dielectric layer 27), the second conductive pads 282 and a portion of the dummy pad 3 (or the dummy structure) may be exposed in the cavity 144.

As shown in FIG. 2 and FIG. 3, the dummy pad 3 (or the dummy structure) may include a first portion 3a (e.g., an inner portion) and a second portion 3b (e.g., an outer portion) surrounding the first portion 3a (e.g., the inner portion). The first portion 3a (e.g., the inner portion) of the dummy pad 3 (or the dummy structure) may be disposed within the vertical projection of the cavity 144. The second portion 3b (e.g., the outer portion) of the dummy pad 3 (or the dummy structure) may be disposed outside the vertical projection of the cavity 144. The first encapsulant 14 may cover a contact the second portion 3b (e.g., the outer portion) of the dummy pad 3 (or the dummy structure). In some embodiments, the inner lateral surface 145 of the first encapsulant 14 may connect to the top surface 31 of the dummy pad 3 (or the dummy structure).

The external connectors 13 may be disposed on the second surface 202 (e.g., the bottom surface) of the metal-containing layer 2. The external connectors 13 may be disposed on the exposed portions of the first conductive vias 223. Each of the external connectors 13 may be a solder material, a bonding material, an electrical connector, a solder bump, a conductive connector, a reflowable connector, or a reflowable material. A material of the external connectors 13 may include Ag/Sn alloy.

The second encapsulant 12 may be disposed on the second surface 202 (e.g., the bottom surface) of the metal-containing layer 2. The second encapsulant 12 may be an epoxy molding compound with or without filler. The second encapsulant 12 may surround the external connectors 13, and may not encapsulate electronic component. The second encapsulant 12 may be also a reinforcement structure. A rigidity and a hardness of the second encapsulant 12 (e.g., the reinforcement structure) may be greater than a rigidity and a hardness of the metal-containing layer 2. The hardness of the second encapsulant 12 (e.g., the reinforcement structure) may be greater than a hardness of the first encapsulant 14. The second encapsulant 12 (e.g., the reinforcement structure) may have a top surface 121, a bottom surface 122 opposite to the top surface 121, and an outer lateral surface 123 extending between the top surface 121 and the bottom surface 122. The top surface 121 of the second encapsulant 12 (e.g., the reinforcement structure) may contact the second surface 202 (e.g., the bottom surface) of the metal-containing layer 2. The outer lateral surface 123 of the second encapsulant 12 (e.g., the reinforcement structure) may be substantially aligned with or substantially coplanar with the lateral surface 203 of the metal-containing layer 2.

A material of the first encapsulant 14 may be different from a material of the second encapsulant 12. A physical property of the first encapsulant 14 may be different from a physical property of the second encapsulant 12. In some embodiments, a coefficient of thermal expansion (CTE) and a modulus of the first encapsulant 14 may be different from a coefficient of thermal expansion (CTE) and a modulus of the second encapsulant 12. The coefficient of thermal expansion (CTE) and the modulus of the second encapsulant 12 may be greater than or less than the coefficient of thermal expansion (CTE) and the modulus of the first encapsulant 14. For example, the coefficient of thermal expansion (CTE) of the first encapsulant 14 may be 6 to 20 ppm/°C, and the coefficient of thermal expansion (CTE) of the second encapsulant 12 may be 6 to 18 ppm/°C. The modulus of the first encapsulant 14 may be 12 GPa to 25 GPa. The modulus of the second encapsulant 12 may be 6 GPa to 25 GPa. In addition, a maximum filler size of the filler of the second encapsulant 12 may be greater than or less than a maximum filler size of the filler of the first encapsulant 14. For example, the maximum filler size of the filler of the first encapsulant 14 may be 5 to 55 μm, and the maximum filler size of the filler of the second encapsulant 12 may be 5 to 25 μm.

The second encapsulant 12 may further have an inner lateral surface 124 to define an opening 126. The inner lateral surface 124 may continuously extend from the top surface 121 of the second encapsulant 12 to the bottom surface 122 of the second encapsulant 12. The external connector 13 (e.g., the solder material) may be disposed in the opening 126. A gap 125 may be formed between the inner lateral surface 124 of the second encapsulant 12 and an outer surface of the external connector 13 (e.g., the solder material). A bottom end 131 of the solder material 13 may extend beyond the bottom surface 122 of the second encapsulant 12. The bottom end 131 of the solder material 13 may be lower than the bottom surface 122 of the second encapsulant 12. In some embodiments, a volume of the bottom end 131 of the solder material 13 may be equal to a volume (or a capacity) of the gap 125.

The second electronic component 18 may be an electronic element or an electronic device, such as a semiconductor chip (e.g., a logic die or a memory die) or a passive element (e.g., a resistor, an inductor or a capacitor). The second electronic component 18 may have a first surface 181 (e.g., a bottom surface) and a second surface 182 (e.g., a top surface) opposite to the first surface 181. The first surface 181 (e.g., the bottom surface) may be an active surface. The second surface 182 (e.g., the top surface) may be a backside surface. The second electronic component 18 may be disposed in the cavity 144. The second electronic component 18 may include a plurality of conductive bumps 184 extending beyond the first surface 181 (e.g., the bottom surface). The conductive bumps 184 of the second electronic component 18 may be electrically connected to the second conductive pads 282 of the metal-containing layer 2 through a plurality of solder materials 17.

The filling material 19 may be formed or disposed between the second electronic component 18 and the sidewall 145 of the cavity 144 (e.g., the inner lateral surface 145 of the first encapsulant 14). The filling material 19 may surround the second electronic component 18. The filling material 19 may cover and protect the connection formed by the conductive bumps 184, the second conductive pads 282 and the solder materials 17. A top surface of the filling material 19 may be not aligned with or coplanar with the top surface 141 of the first encapsulant 14. The material of the first encapsulant 14 may be different from a material of the filling material 19. For example, the filling material 19 may include an underfill. In some embodiments, the filling material 19 may cover and contact the dummy pad 3 (e.g., including the first strip portion 34, the second strip portion 35, the third strip portion 36 and the fourth strip portion 37). Thus, there may be three different materials (e.g., the filling material 19, the first encapsulant 14 and the underfill 11) that contact the third strip portion 36 of the dummy pad 3 (or the dummy structure).

In the embodiment illustrated in FIG. 1 to FIG. 4, the second electronic component 18 may be mounted to or attached to the metal-containing layer 2 after the formation of the cavity 144 of the first encapsulant 14. Thus, during the manufacturing process, the second electronic component 18 and the electronic package structure 1 (including the metal-containing layer 2, the reinforcement structure, the first electronic component 16, the underfill 11 and the first encapsulant 14) may be tested individually before being bonded together. Therefore, only known good second electronic component 18 and known good electronic package structure 1 may be bonded together. Bad (or unqualified) second electronic component 18 and bad (or unqualified) electronic package structure 1 may be discarded. As a result, the yield of the final electronic package structure 1 (including the second electronic component 18) (e.g., the assembly structure) may be improved. In addition, the electronic package structure 1 may include at least one reinforcement structure (e.g., the dummy pad 3, the first reinforcement structure 4, the second reinforcement structure 5 and the second encapsulant 12) to reinforce or enhance the strength or rigidity of the electronic package structure 1 that defines the cavity 144 of the first encapsulant 14. That is, the strength reduction of the electronic package structure 1 caused by the formation of the cavity 144 can be reinforced by the at least one reinforcement structure (e.g., the dummy pad 3, the first reinforcement structure 4, the second reinforcement structure 5 and the second encapsulant 12).

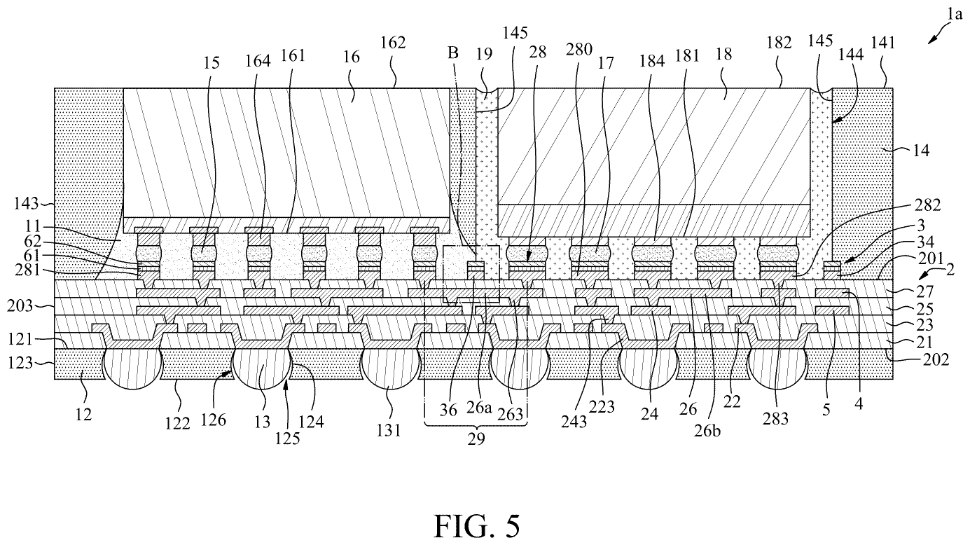

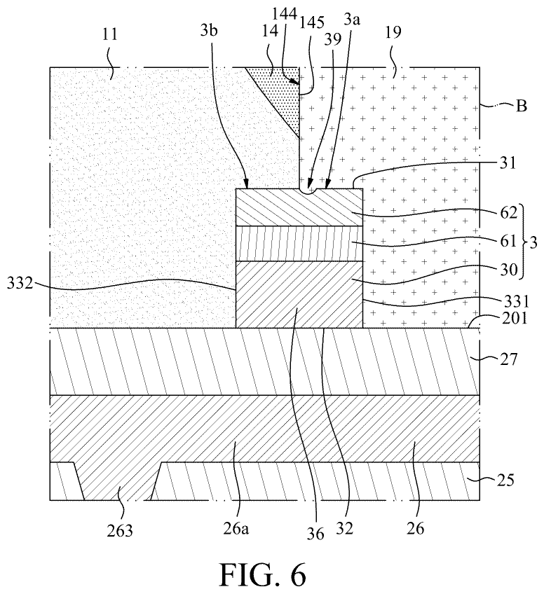

FIG. 5 illustrates a cross-sectional view of an electronic package structure 1a according to some embodiments of the present disclosure. FIG. 6 illustrates an enlarged view of an area “B” of FIG. 5. The electronic package structure 1a of FIG. 5 and FIG. 6 may be similar to the electronic package structure 1 of FIG. 1 to FIG. 4, and the differences are described as follow. As shown in FIG. 5 and FIG. 6, the underfill 11 may be exposed in the cavity 144. A lateral surface of the underfill 11 may be substantially aligned with or substantially coplanar with the inner lateral surface 145 of the first encapsulant 14 (or the sidewall 145 of the cavity 144). Thus, the underfill 11 may contact the top surface 31 of the dummy pad 3 and the filling material 19. The first encapsulant 14 may not contact the third strip portion 36 of the dummy pad 3 (or the dummy structure or the reinforcement structure).

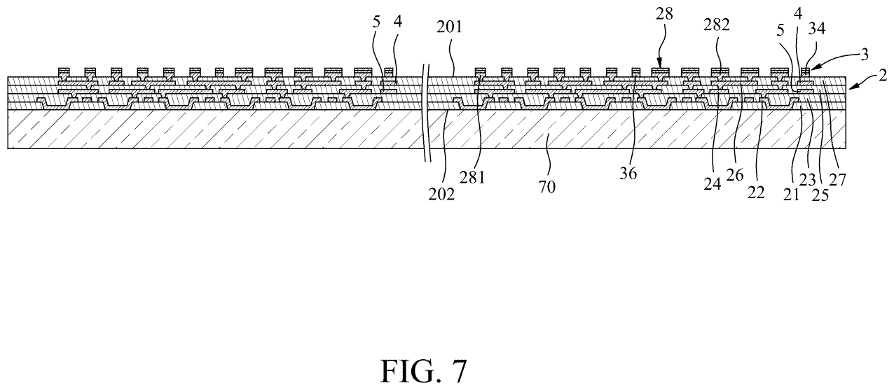

FIG. 7 through FIG. 20 illustrate a method for manufacturing an electronic package structure according to some embodiments of the present disclosure. In some embodiments, the method is for manufacturing the electronic package structure 1 shown in FIG. 1.

Referring to FIG. 7, a carrier 70 with a release layer may be provided. The carrier 7 may be a glass substrate or a FR4 substrate. The carrier 70 may be in a panel type (or a panel structure) or a wafer type (or a wafer structure). In some embodiments, the carrier 70 may be in a panel type (or a panel structure) and may be square or rectangular from a top view.

Then, a metal-containing layer 2 may be formed or disposed on the release layer on the carrier 70. The metal-containing layer 2 of FIG. 7 may be similar to the metal-containing layer 2 of FIG. 1, and may have a first surface 201 (e.g., a top surface) and a second surface 202 (e.g., a bottom surface) opposite to the first surface 201. The metal-containing layer 2 may include the first dielectric layer 21, the second dielectric layer 23, the third dielectric layer 25, the fourth dielectric layer 27, the first circuit layer 22, the second circuit layer 24, the third circuit layer 26 the fourth circuit layer 28, the first conductive vias 223, the second conductive vias 243, the third conductive vias 263, the fourth conductive vias 283, the first conductive pads 281 and the second conductive pads 282.

In addition, the metal-containing layer 2 may further include the dummy pad 3 (e.g., the block structure) on the first surface 201 (e.g., the top surface) of the metal-containing layer 2. In addition, the metal-containing layer 2 may further include the first reinforcement structure 4 and the second reinforcement structure 5 embedded in the metal-containing layer 2.

In some embodiments, the metal-containing layer 2 may be in a panel type (or a panel structure) and may be square or rectangular from a top view. The metal-containing layer 2 may include a plurality of units defined by a plurality of cutting lines crossed with each other. The units may be arranged in an N×M array with N rows and M columns. Each row includes the same number of units. Each row includes M units. Each column includes the same number of units. Each column includes N units. The cutting lines may be parallel with the edges of the metal-containing layer 2. The distribution density of the units in the center of the metal-containing layer 2 may be equal to the distribution density of the units in the periphery of the metal-containing layer 2.

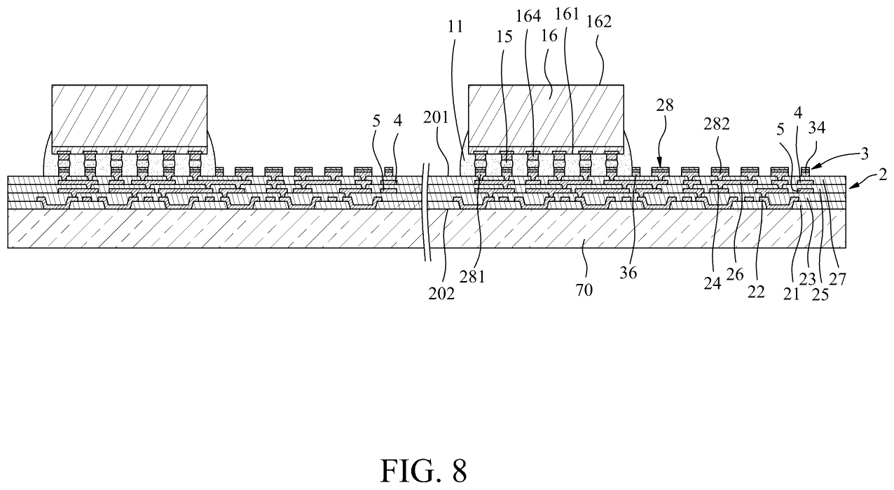

Referring to FIG. 8, a first electronic component 16 may be may electrically connected to the first conductive pads 281 on the first surface 201 (e.g., the top surface) of the metal-containing layer 2 through a plurality of solder materials 15. The first electronic component 16 of FIG. 8 may be the same as the first electronic component 16 of FIG. 1. An underfill 11 may be formed or disposed between the first electronic component 16 and the metal-containing layer 2. The underfill 11 may be blocked by the dummy pad 3 (e.g., the block structure).

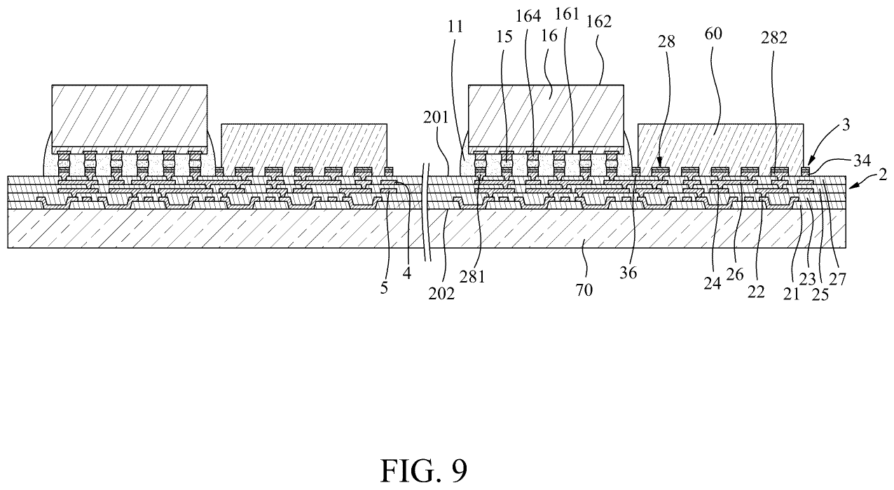

Referring to FIG. 9, a protection material 60 may be attached or disposed on the first surface 201 (e.g., the top surface) of the metal-containing layer 2. The protection material 60 may include a protection tape or a water-washable adhesive. The protection material 60 may cover, contact and protect the second conductive pads 282 the metal-containing layer 2. The protection material 60 may cover and contact a portion of the dummy pad 3 (e.g., the block structure) such as the first portion 3a (e.g., the inner portion) of FIG. 2 and FIG. 3. The other portion of the dummy pad 3 (e.g., the block structure) such as the second portion 3b (e.g., the outer portion) of FIG. 2 and FIG. 3 may be exposed by the protection material 60. The protection material 60 may cover and contact the first strip portion 34, the second strip portion 35, the third strip portion 36 and the fourth strip portion 37 (FIG. 3). The protection material 60 may cover and contact the top surface 31 (FIG. 2) of the dummy pad 3 (e.g., the block structure). A top surface of the protection material 60 may be lower than the second surface 162 (e.g., the top surface) of the first electronic component 16. The protection material 60 may not extend beyond the outer lateral surface 332 (FIG. 3) of the dummy pad 3 (e.g., the block structure).

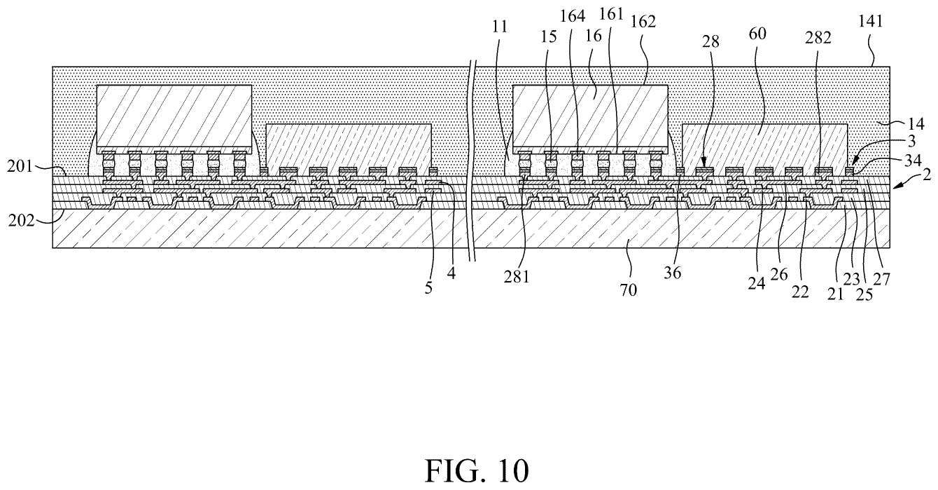

Referring to FIG. 10, a first encapsulant 14 may be formed or disposed on the first surface 201 (e.g., the top surface) of the metal-containing layer 2 to encapsulate the first electronic component 16, the underfill 11, the protection material 60 and a portion of the dummy pad 3 (e.g., the block structure) such as the second portion 3b (e.g., the outer portion) of FIG. 2 and FIG. 3. The first encapsulant 14 may have a top surface 141.

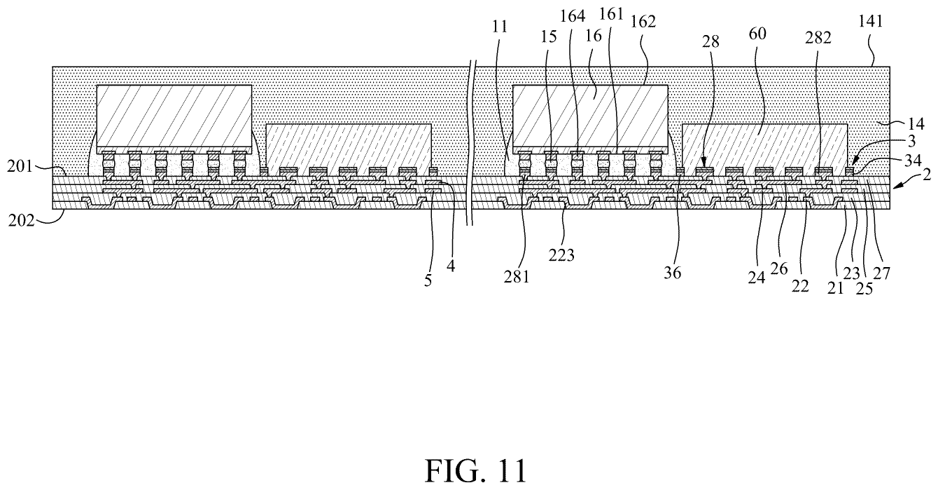

Referring to FIG. 11, the carrier 70 and the release layer may be removed, so that the second surface 202 (e.g., the bottom surface) of the metal-containing layer 2 may be exposed. In addition, the first conductive vias 223 may be exposed by the second surface 202 (e.g., the bottom surface) of the metal-containing layer 2.

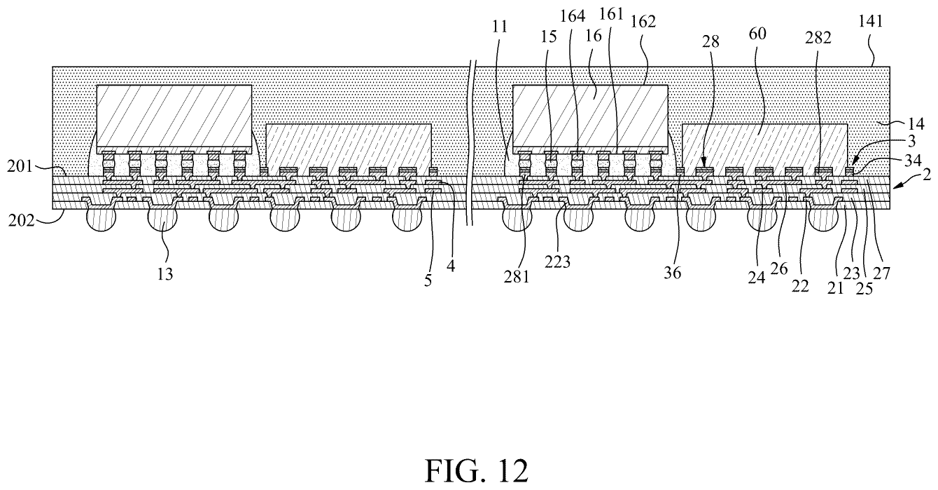

Referring to FIG. 12, a plurality of external connectors 13 may be formed or disposed on the second surface 202 (e.g., the bottom surface) of the metal-containing layer 2. The external connectors 13 may be formed or disposed on the exposed portions of the first conductive vias 223. Each of the external connectors 13 may be a solder material, a bonding material, an electrical connector, a solder bump, a conductive connector, a reflowable connector, or a reflowable material.

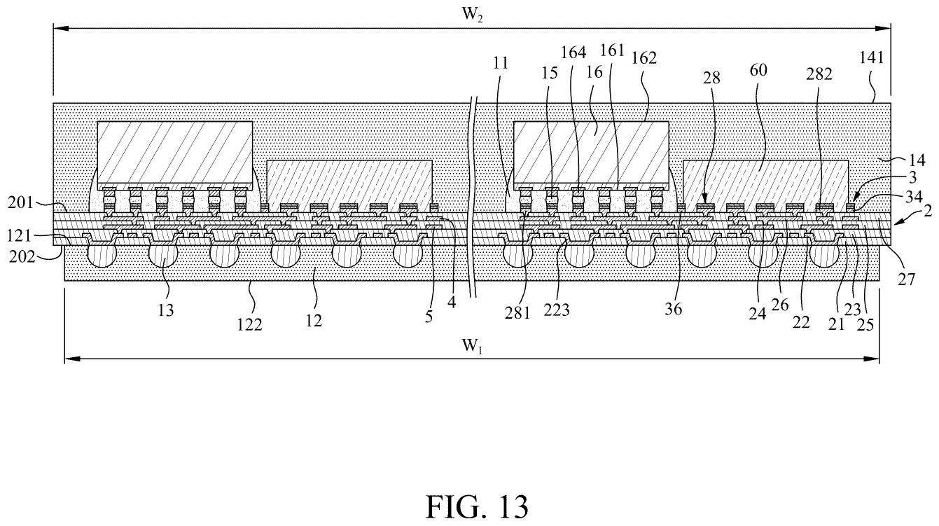

Referring to FIG. 13, a second encapsulant 12 may be formed or disposed on the second surface 202 (e.g., the bottom surface) of the metal-containing layer 2 to surround the external connectors 13. The second encapsulant 12 may cover and encapsulate the entirety of each of the external connectors 13. The second encapsulant 12 may have a top surface 121 and a bottom surface 122 opposite to the top surface 121. The top surface 121 of the second encapsulant 12 may contact the second surface 202 (e.g., the bottom surface) of the metal-containing layer 2. The bottom surface 122 of the second encapsulant 12 may be lower than the external connectors 13. A width W₁ of the second encapsulant 12 may be less than a width W₂ of the first encapsulant 14.

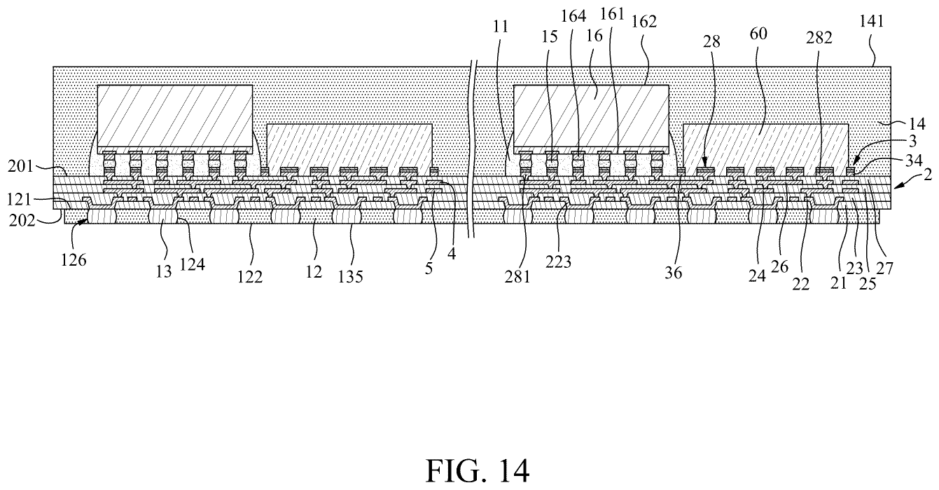

Referring to FIG. 14, a grinding process may be performed on the bottom surface 122 of the second encapsulant 12 to thin the second encapsulant 12. A lower portion of the second encapsulant 12 and a lower portion of each of the external connectors 13 may be removed concurrently. Each of the external connectors 13 may have a truncated surface 135 that is substantially aligned with or substantially coplanar with the bottom surface 122 of the second encapsulant 12 after the grinding process. The second encapsulant 12 may further have an inner lateral surface 124 to define an opening 126. The inner lateral surface 124 may continuously extend from the top surface 121 of the second encapsulant 12 to the bottom surface 122 of the second encapsulant 12. The external connector 13 (e.g., the solder material) may be disposed in the opening 126.

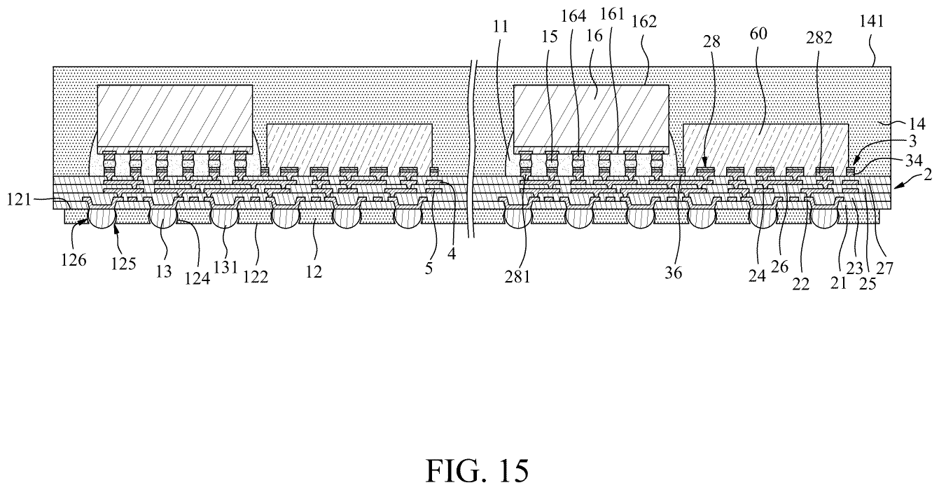

Referring to FIG. 15, a reflow process may be performed so that the truncated external connector 13 may melt to form a substantially ball shape. A gap may be formed between the inner lateral surface 124 of the second encapsulant 12 and an outer surface of the external connector 13 (e.g., the solder material). A bottom end 131 of the solder material 13 may extend beyond the bottom surface 122 of the second encapsulant 12. The bottom end 131 of the solder material 13 may be lower than the bottom surface 122 of the second encapsulant 12. In some embodiments, a volume of the bottom end 131 of the external connector 13 (e.g., the solder material) may be equal to a volume (or a capacity) of the gap 125. In some embodiments, a solder paste printing may be further performed to increase the volume of the external connector 13 (e.g., the solder material).

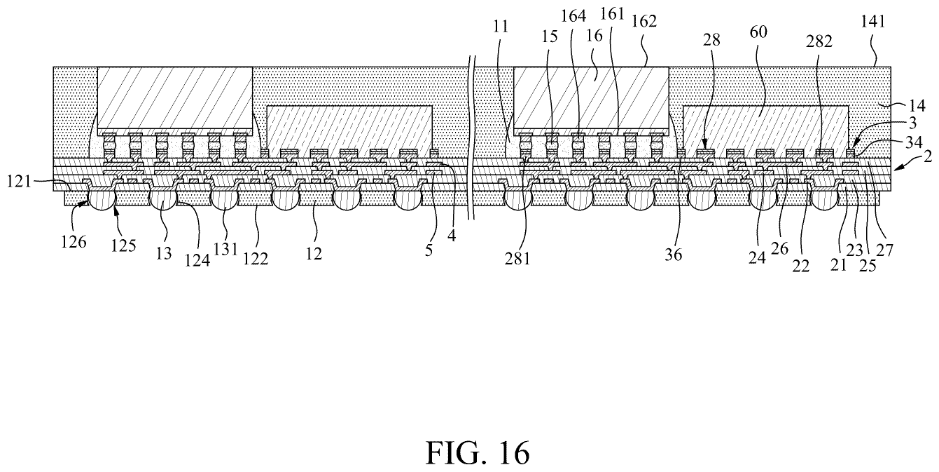

Referring to FIG. 16, a grinding process may be performed on the top surface 141 of the first encapsulant 14 to thin the first encapsulant 14. Thus, the top surface 141 of the first encapsulant 14 may be substantially aligned with or substantially coplanar with the second surface 162 (e.g., the top surface) of the first electronic component 16.

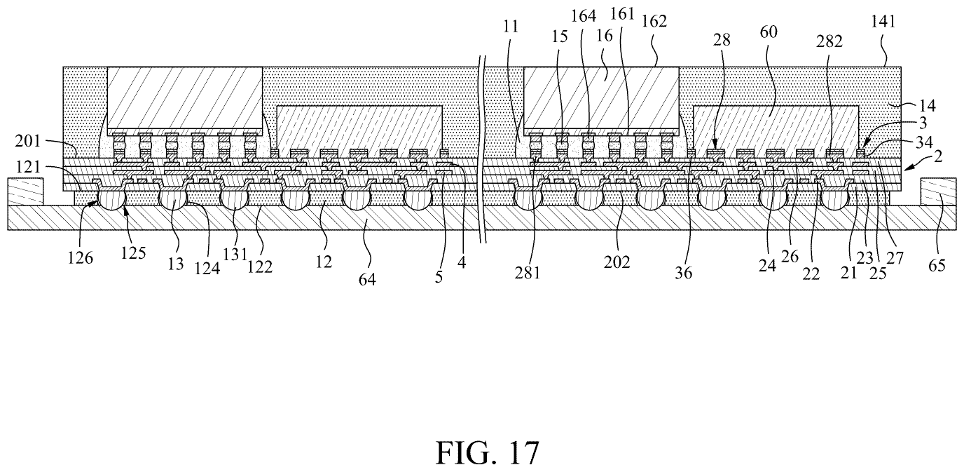

Referring to FIG. 17, the structure of FIG. 16 may be attached to a tape 64 (e.g., a dicing tape) of a frame 65. The bottom end 131 of the external connector 13 may be embedded in the tape 64. The bottom surface 122 of the second encapsulant 12 may contact the top surface of the tape 64.

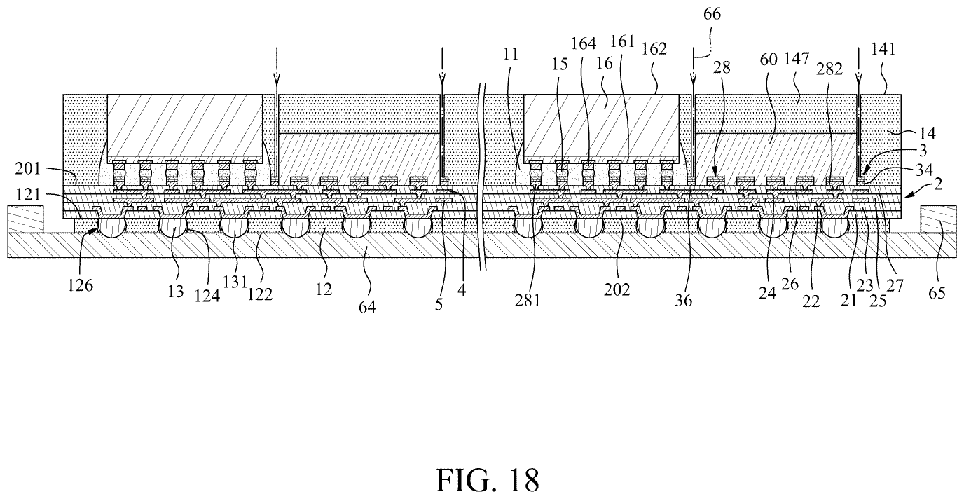

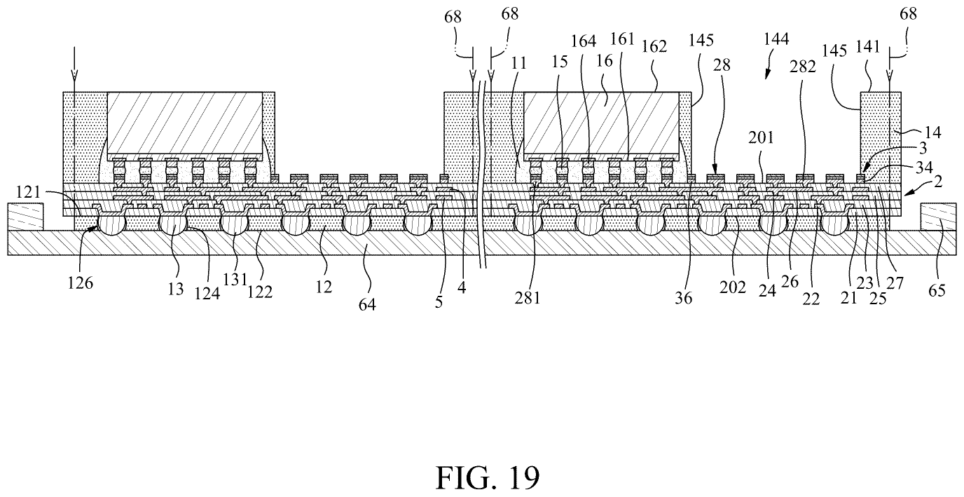

Referring to FIG. 18 and FIG. 19, the protection material 60 and a portion 147 of the first encapsulant 14 that is disposed on the protection material 60 may be removed by laser grooving or laser ablation. Referring to FIG. 18, the step of removing the protection material 60 and the portion 147 of the first encapsulant 14 may be performed by using or applying a laser 66 on the top surface 141 of the first encapsulant 14. The laser 66 may extend through the first encapsulant 14, and may reach to and blocked by the dummy pad 3 (e.g., the block structure). Thus, a moving path of the laser 66 may be along the first strip portion 34, the second strip portion 35, the third strip portion 36 and the fourth strip portion 37 of the dummy pad 3 (e.g., the block structure). Alternatively, the moving path of the laser 66 may be along the edges of the protection material 60. The dummy pad 3 (e.g., the block structure) may be configured to prevent the laser 66 from damaging the metal-containing layer 2. The laser 66 may cut off the connection between the lateral surface of the protection material 60 and first encapsulant 14. Thus, the protection material 60 and the portion 147 of the first encapsulant 14 may be separated from the first encapsulant 14.

Referring to FIG. 19, the protection material 60 and the portion 147 of the first encapsulant 14 may be removed from the metal-containing layer 2. For example, the protection material 60 and the portion 147 of the first encapsulant 14 may be taken out from the metal-containing layer 2 by a suction head. As a result, the first encapsulant 14 may define a cavity 144 extending through the first encapsulant 14. The cavity 144 may be defined by the inner lateral surface 145 the first encapsulant 14 that is formed by the laser 66. Thus, the cavity 144 may have a sidewall 145. A portion of the first surface 201 (e.g., the top surface) of the metal-containing layer 2 (i.e., a portion of the top surface of the fourth dielectric layer 27), the second conductive pads 282 and a portion of the dummy pad 3 (e.g., the block structure) may be exposed in the cavity 144.

Then, a singulation process may be performed by a cutting tool (e.g., a sawing tool) along the cutting lines 68.

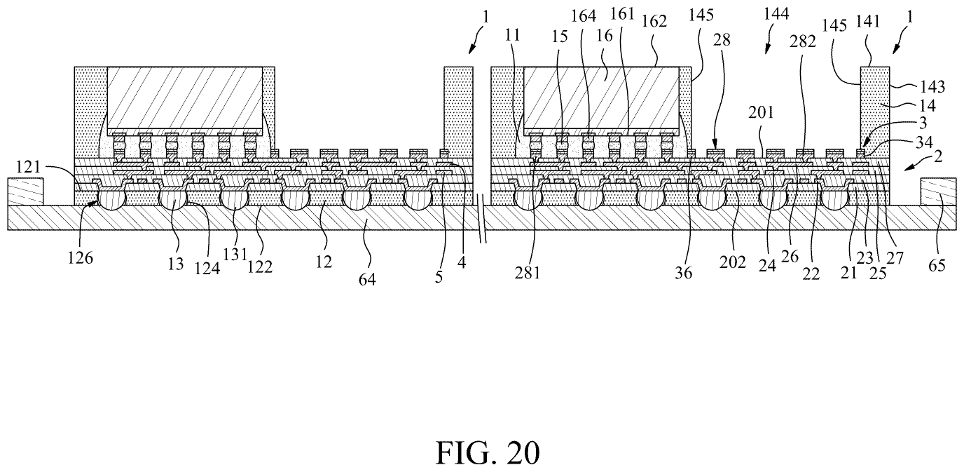

Referring to FIG. 20, after the singulation process, a plurality of electronic package structures 1 may be formed. Then, the electronic package structures 1 may be picked and placed into a tray. Then, a second electronic component 18 may be disposed in the cavity 144. The conductive bumps 184 of the second electronic component 18 may be electrically connected to the second conductive pads 282 of the metal-containing layer 2 through a plurality of solder materials 17. Then, a filling material 19 may be formed or disposed between the second electronic component 18 and the sidewall 145 of the cavity 144 (e.g., the inner lateral surface 145 of the first encapsulant 14). The filling material 19 may surround the second electronic component 18. The filling material 19 may cover and protect the connection formed by the conductive bumps 184, the second conductive pads 282 and the solder materials 17. In some embodiments, the filling material 19 may cover and contact the dummy pad 3 (e.g., including the first strip portion 34, the second strip portion 35, the third strip portion 36 and the fourth strip portion 37). Thus, the electronic package structures 1 may become an assembly structure that includes second electronic component 18 the filling material 19, as shown in FIG. 1 to FIG. 4.

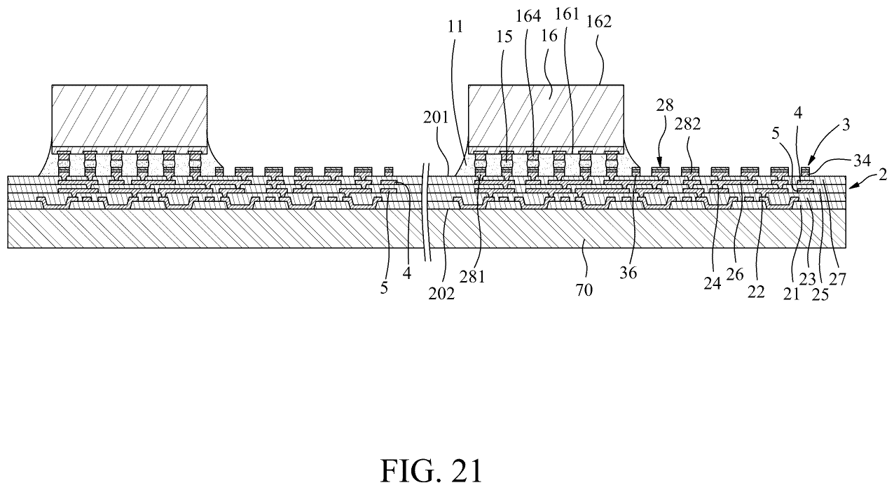

FIG. 21 through FIG. 23 illustrate a method for manufacturing an electronic package structure according to some embodiments of the present disclosure. In some embodiments, the method is for manufacturing the electronic package structure 1a shown in FIG. 5 and FIG. 6. The initial stage of the illustrated process is the same as, or similar to, the stage illustrated in FIG. 7. FIG. 21 depicts a stage subsequent to that depicted in FIG. 7.

Referring to FIG. 21, the underfill 11 may cover and contact the top surface 31 (FIG. 6) of the dummy pad 3.

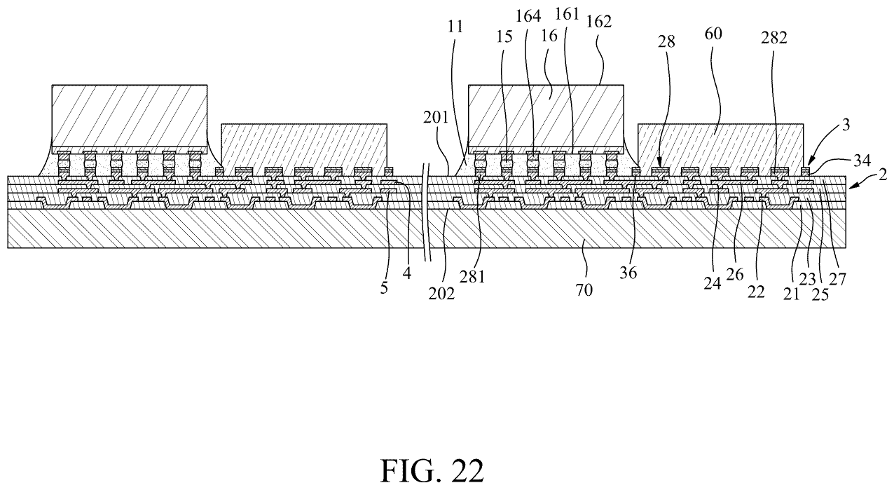

Referring to FIG. 22, the protection material 60 may cover and contact a portion of the underfill 11.

Then, the following stages of the illustrated process are the same as, or similar to, the stages illustrated in FIG. 10 through FIG. 17.

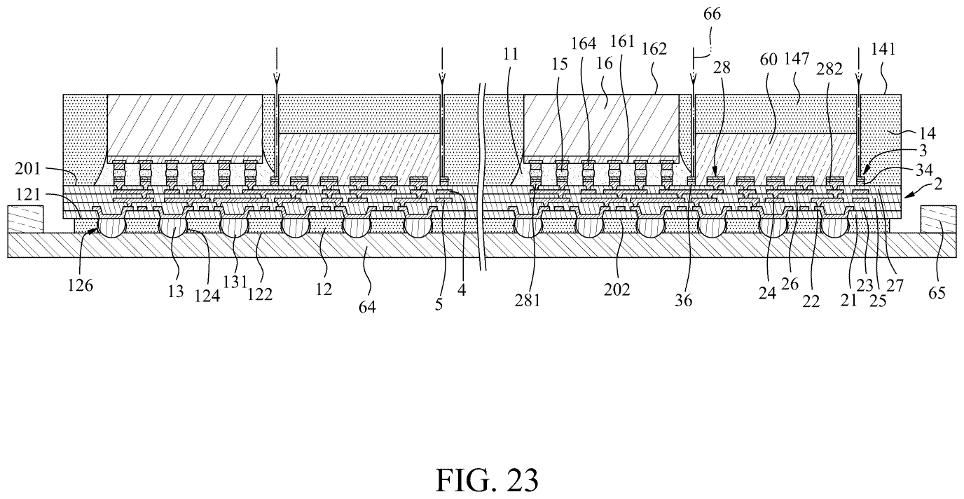

Referring to FIG. 23, the protection material 60 and a portion 147 of the first encapsulant 14 that is disposed on the protection material 60 may be removed by laser grooving or laser ablation. The laser 66 may extend through the first encapsulant 14, and may reach to and blocked by the dummy pad 3 (e.g., the block structure). The laser 66 may ablate a portion of the underfill 11. Thus, after the protection material 60 and the portion 147 of the first encapsulant 14 are removed, the underfill 11 may be exposed in the cavity 144 as shown in FIG. 5 and FIG. 6.

Then, the following stages of the illustrated process are the same as, or similar to, the stages illustrated in FIG. 19 through FIG. 20, so as to obtain the electronic package structure 1a shown in FIG. 5 and FIG. 6.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic package structure, comprising:
a metal-containing layer;
an electronic component disposed over the metal-containing layer;
an encapsulant encapsulating the electronic component, and defining a designated cavity; and
a reinforcement structure contacting the metal-containing layer, and overlapping a vertical projection of the designated cavity, wherein a rigidity of the reinforcement structure is greater than a rigidity of the metal-containing layer.

2. The electronic package structure of claim 1, wherein the reinforcement structure is disposed on a bottom surface of the metal-containing layer, wherein a hardness of the reinforcement structure is greater than a hardness of the metal-containing layer.

3. The electronic package structure of claim 2, wherein the hardness of the reinforcement structure is greater than a hardness of the encapsulant.

4. The electronic package structure of claim 1, wherein the reinforcement structure is disposed within the metal-containing layer, and a width of the reinforcement structure is greater than a width of a trace of a circuit layer of the metal-containing layer.

5. The electronic package structure of claim 4, wherein the reinforcement structure and the circuit layer of the metal-containing layer are at a same layer and are formed concurrently.

6. The electronic package structure of claim 1, wherein the reinforcement structure includes a dummy pad disposed on a top surface of the metal-containing layer, wherein the dummy pad is electrically insulated from a circuit layer of the metal-containing layer.

7. The electronic package structure of claim 6, wherein the metal-containing layer includes a plurality of conductive pads disposed on the top surface of the metal-containing layer and electrically connected to the circuit layer of the metal-containing layer, wherein the dummy pad is disposed at least two sides of the plurality of conductive pads.

8. The electronic package structure of claim 1, wherein a first portion of the reinforcement structure is disposed within the vertical projection of the designated cavity, and a second portion of the reinforcement structure is disposed outside the vertical projection of the designated cavity.

9. An electronic package structure, comprising:
a metal-containing layer;
a first electronic component electrically connected to the metal-containing layer;
a first encapsulant disposed on a top surface of the metal-containing layer and encapsulating the first electronic component, wherein the first encapsulant defines a designated cavity extending through the first encapsulant; and
a second encapsulant disposed on a bottom surface of the metal-containing layer.

10. The electronic package structure of claim 9, wherein a coefficient of thermal expansion (CTE) of the first encapsulant is different from a coefficient of thermal expansion (CTE) of the second encapsulant.

11. The electronic package structure of claim 9, further a solder material disposed on the bottom surface of the metal-containing layer, wherein the second encapsulant surrounds the solder material.

12. The electronic package structure of claim 9, further comprising:
a second electronic component disposed in the designated cavity and electrically connected to the metal-containing layer; and
a filling material disposed between the second electronic component and a sidewall of the designated cavity.

13. The electronic package structure of claim 9, further comprising:
a block structure disposed on the metal-containing layer and exposed in the designated cavity.

14. The electronic package structure of claim 13, further comprising:
an underfill disposed between the first electronic component and the metal-containing layer, wherein the underfill contacts the block structure.

15. The electronic package structure of claim 14, wherein the underfill is exposed in the designated cavity.

16. A method for manufacturing an electronic package structure, comprising:
attaching a first electronic component on a top surface of a metal-containing layer;
attaching a protection material on the top surface of the metal-containing layer;
forming a first encapsulant on the metal-containing layer to encapsulate the first electronic component and the protection material; and
removing the protection material and a portion of the first encapsulant disposed on the protection material, so that the first encapsulant defines a designated cavity extending through the first encapsulant.

17. The method of claim 16, wherein the metal-containing layer includes a block structure on the top surface of the metal-containing layer.

18. The method of claim 17, wherein the step of removing the protection material and the portion of the first encapsulant is performed by using a laser, wherein the laser is blocked by the block structure.

19. The method of claim 16, further comprising:
forming an underfill between the first electronic component and the metal-containing layer,
wherein the step of removing the protection material and the portion of the first encapsulant is performed by using a laser, wherein the laser ablates a portion of the underfill.

20. The method of claim 16, further comprising:
forming a solder material on a bottom surface of the metal-containing layer; and
forming a second encapsulant on the bottom surface of the metal-containing layer to surround the solder material.
